(19) United States
(12) Patent Application Publication
(10) Pub. No.: US 2026/0286186 A1
(43) Pub. Date: Sep. 24, 2026

(54) POLISHING SLURRY AND METHOD OF MANUFACTURING SEMICONDUCTOR DEVICE

(71) Applicants: SAMSUNG ELECTRONICS CO., LTD., Suwon-si (KR); UIF (University Industry Foundation), Yonsei University, Seoul (KR)

(72) Inventors: Yongtae Park, Suwon-si (KR); Byeong-Su KIM, Seoul (KR); WOOSUNG JEON, Suwon-si (KR); DOYOON KIM, Suwon-si (KR); Nohjun Park, Suwon-si (KR); Aram Shin, Seoul (KR); Byungwoo Yoo, Seoul (KR); JAEHOON RYU, Suwon-si (KR); Yeonah Jeong, Suwon-si (KR)

(21) Appl. No.: 19/467,278

(22) Filed: Feb. 2, 2026

(30) Foreign Application Priority Data
Feb. 18, 2025 (KR) 10-2025-0021103

(51) Int. Cl. C09G 1/04; C08G 65/26; C08G 65/324; C08G 65/326; H10P 52/40

(52) U.S. Cl. CPC C09G 1/04; C08G 65/2609; C08G 65/2612; C08G 65/324; C08G 65/326; H10P 52/403

(57) ABSTRACT

Disclosed are a polishing slurry and a method of manufacturing a semiconductor device, the polishing slurry that includes: a branched polymer including a hydrophobic unit, a micelle of the branched polymers, or a combination thereof, and a dispersion medium.

### CROSS-REFERENCE TO RELATED APPLICATION

This application claims priority to and the benefit of Korean Patent Application No. 10-2025-0021103 filed on Feb. 18, 2025, in the Korean Intellectual Property Office and all the benefits accruing therefrom under 35 U.S.C. § 119, the contents of which are incorporated herein in their entireties by reference.

### BACKGROUND

### 1. Field

A polishing slurry and a method of manufacturing a semiconductor device are disclosed.

### 2. Description of the Related Art

In line with miniaturization of electronic devices and the resulting miniaturization of integrated circuits, various methods of forming microstructures with a width of several nanometers such as metal wires, contact holes, or shallow trench isolations have been studied.

In forming such microstructures, polishing processes may be performed to make the surface of the microstructures flat and smooth, and chemical mechanical polishing (CMP) may be one of the polishing processes. Chemical mechanical polishing is a process of polishing an object to be polished by providing polishing slurry.

### SUMMARY

In order to improve the chemical mechanical polishing performance, a polishing rate may be increased in order to polish an object such as a metal layer. In addition, to the polishing selectivity may need to be increased with respect to adjacent layers to reduce defects caused by scratches or particle residues.

An embodiment provides a polishing slurry capable of increasing polishing selectivity with respect to adjacent layers and reducing defects caused by scratches or particle residues.

Another embodiment provides a method of manufacturing a semiconductor device capable of increasing polishing selectivity with respect to adjacent layers and reducing defects caused by scratches or particle residues.

According to an embodiment, a polishing slurry includes a branched polymer including a hydrophobic unit, micelles of the branched polymer, or a combination thereof, and a dispersion medium.

The hydrophobic unit may include a substituted or unsubstituted C1 to C30 alkyl group, a substituted or unsubstituted C3 to C30 cycloalkyl group, a substituted or unsubstituted C2 to C30 alkenyl group, a substituted or unsubstituted C3 to C30 cycloalkenyl group, a substituted or unsubstituted C2 to C30 alkynyl group, a substituted or unsubstituted C6 to C30 aromatic group, a substituted or unsubstituted siloxane group, or a combination thereof.

The branched polymer may further include a hydrophilic functional group positioned at the terminal of the branched polymer, and the hydrophilic functional group may include a hydroxyl group, a sulfonate group, a carboxylate group, a phosphonate group, an ammonium group, a pyrrolidium group, an imidazolium group, an amino group, an amide group, an aldehyde group, a ketone group, an epoxide group, or a combination thereof.

The branched polymer may include one or more structural units derived from glycerol, ethylene glycol, propylene glycol, ethylene imine, piperazine, trimethylolpropane, sorbitol, acrylic acid, methacrylic acid, a derivative thereof, or a combination thereof.

The branched polymer may include 3 to 100 structural units.

The branched polymer may include one or more structural units (also referred to as a repeating unit or repeating structural unit) represented by Chemical Formula A and a terminal moiety represented by Chemical Formula B.

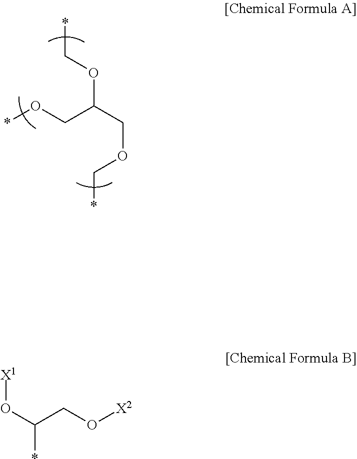

In Chemical Formula A or B,
X¹ and X² may each independently be hydrogen or a hydrophilic functional group, and the symbol “*” may be a linking point to an adjacent structural unit or a terminal moiety.
   X¹ and X² of Chemical Formula B may each independently be hydrogen, a sulfonate group, a carboxylate group, a phosphonate group, an ammonium group, a pyrrolidium group, imidazolium group, an amino group, an amide group, an aldehyde group, a ketone group, an epoxide group, or a combination thereof.

In the branched polymer, the terminal moiety represented by Chemical Formula B may be a starting portion of the branched polymer, and the structural unit represented by Chemical Formula A may be located between the hydrophobic unit and the terminal moiety represented by Chemical Formula B.

A weight average molecular weight of the branched polymer may be about 300 g/mol (grams per mole) to about 5,000 g/mol.

The micelle may be in the form of an assembly or aggregate of a plurality of the branched polymers, and the micelle may include a core in which the hydrophobic units are assembled, and a shell including a polymer segment, the polymer segment includes a hydrophilic functional group and a structural unit derived from glycerol, ethylene glycol, propylene glycol, ethylene imine, piperazine, trimethylolpropane, sorbitol, acrylic acid, methacrylic acid, a derivative thereof, or a combination thereof.

A particle size of the micelles measured by a dynamic light scattering method in an aqueous medium may be about 1 nm to about 50 nm.

The branched polymer, the micelle, or a combination thereof may be included in an amount of about 0.1 to about 30 wt % based on a total amount of the polishing slurry.

The polishing slurry may further include an oxidizing agent and may not include an inorganic abrasive.

According to another embodiment, a method of manufacturing a semiconductor device includes: forming a conductive layer (e.g., metal layer) on a dielectric layer having a trench, supplying a polishing slurry on the conductive layer (e.g., the metal layer), performing chemical mechanical polishing on conductive layer (e.g., the metal layer) to form a conductive pattern (e.g., a metal pattern) embedded in the trench, wherein the polishing slurry includes a branched polymer including a hydrophobic unit, a micelle of the branched polymers, or a combination thereof, and a dispersion medium.

The hydrophobic unit may include a substituted or unsubstituted C1 to C30 alkyl group, a substituted or unsubstituted C3 to C30 cycloalkyl group, a substituted or unsubstituted C2 to C30 alkenyl group, a substituted or unsubstituted C3 to C30 cycloalkenyl group, a substituted or unsubstituted C2 to C30 alkynyl group, a substituted or unsubstituted C6 to C30 aromatic group, a substituted or unsubstituted siloxane group, or a combination thereof, and the branched polymer may further include one or more structural units derived from glycerol, ethylene glycol, propylene glycol, ethylene imine, piperazine, trimethylolpropane, sorbitol, acrylic acid, methacrylic acid, a derivative thereof, or a combination thereof, and a hydrophilic functional group including a hydroxyl group, a sulfonate group, a carboxylate group, a phosphonate group, an ammonium group, a pyrrolidium group, an imidazolium group, an amino group, an amide group, an aldehyde group, a ketone group, an epoxide group, or a combination thereof.

The branched polymer may include the structural unit represented by Chemical Formula A and the terminal moiety represented by Chemical Formula B.

The branched polymer or the micelle of the branched polymers may be included in an amount of about 0.1 to about 30 wt % based on a total amount of the polishing slurry, and a temperature of the polishing slurry in the performing of the chemical mechanical polishing may be room temperature to about 70° C.

The micelle may be in a form of an assembly or aggregate of a plurality of the branched polymers, and each of the micelles may include a core in which the hydrophobic units are assembled, and a shell including hydrophilic functional groups and one or more structural units derived from glycerol, ethylene glycol, propylene glycol, ethylene imine, piperazine, trimethylolpropane, sorbitol, acrylic acid, methacrylic acid, a derivative thereof, or a combination thereof.

A particle size of the micelle measured by a dynamic light scattering method in an aqueous medium may be about 1 nm to about 50 nm.

According to another embodiment, a micelle of branched polymers includes a core in which hydrophobic units are assembled, and a shell including hydrophilic functional groups and one or more structural units derived from glycerol, ethylene glycol, propylene glycol, ethylene imine, piperazine, trimethylolpropane, sorbitol, acrylic acid, methacrylic acid, a derivative thereof, or a combination thereof, and a particle size of the micelle measured by a dynamic light scattering method in an aqueous medium is about 1 nm to about 50 nm.

It may effectively reduce defects caused by scratches or particle residues while increasing the polishing selectivity.

### BRIEF DESCRIPTION OF THE DRAWINGS

FIG. 1 is a schematic view showing an example of a branched polymer and a micelle thereof according to an embodiment,

FIGS. 2 to 5 are cross-sectional views showing an example of a method of manufacturing a semiconductor device according to an embodiment,

FIG. 6 is a schematic view showing a chemical mechanical polishing equipment according to an embodiment,

FIG. 7A is an SEM image of a surface of a polished product of chemical mechanical polishing according to Example 4,

FIG. 7B is an SEM image of a cross-section of a polished product of chemical mechanical polishing according to Example 4,

FIG. 7C is an SEM image of a surface of a polished product of chemical mechanical polishing according to Example 1,

FIG. 8A is an SEM image of a surface of a polished product of chemical mechanical polishing according to Reference Example 1, and

FIG. 8B is an SEM image of a cross-section of a polished product of chemical mechanical polishing according to Reference Example 1.

### DETAILED DESCRIPTION

Example embodiments will hereinafter be described in detail, and may be easily performed by a person having an ordinary skill in the related art. However, this disclosure may be embodied in many different forms and is not to be construed as limited to the exemplary embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it may be directly on the other element or intervening elements may also be present. In contrast, when an element is referred to as being “directly on” another element, there are no intervening elements present.

As used herein, when a definition is not otherwise provided, ‘substituted’ refers to replacement of hydrogen of a compound or a group by a substituent selected from a halogen atom, a hydroxy group, a nitro group, a cyano group, an amino group, an azido group, an amidino group, a hydrazino group, a hydrazono group, an acyl group, a carbamyl group, a thiol group, an ester group, a carboxyl group or a salt thereof, a sulfonic acid group or a salt thereof, a phosphoric acid group or a salt thereof, a silyl group, a C1 to C20 alkyl group, a C2 to C20 alkenyl group, a C2 to C20 alkynyl group, a C6 to C30 aryl group, a C7 to C30 arylalkyl group, a C1 to C30 alkoxy group, a C1 to C20 heteroalkyl group, a C3 to C20 heteroaryl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and a combination thereof.

As used herein, when a definition is not otherwise provided, ‘hetero’ means including 1 to 4 heteroatoms selected from N, O, S, Se, Te, Si, and P.

Hereinafter, the term ‘combination’ includes a mixture or a stacked structure of two or more.

Hereinafter, a polishing slurry according to an embodiment is described.

The polishing slurry may be used to planarize a solid surface or remove steps on a solid surface by being provided on a surface of an object to be polished (dielectric layer or conductive layer) in a manufacturing process of a semiconductor device.

A polishing slurry according to an embodiment includes a branched polymer, a micelle of the branched polymers, or a combination thereof, and a dispersion medium.

The branched polymer may be a macromolecule in which side chains extend regularly or irregularly from the main chain of the polymer, and may have a plurality of branch points where two or more chains are connected.

The branched polymer may include a polymer segment in which repeating structural units (repeating units) of the polymer are distributed, and a hydrophobic unit bonded to the polymer segment. The polymer segment includes a hydrophilic functional group positioned at the end thereof. The moiety of the polymer segment other than the hydrophilic functional group may be located between the hydrophobic unit and the hydrophilic functional group. One polymer segment may correspond to one hydrophobic unit and two or more hydrophilic functional groups.

The polymer segment may include branch points and a plurality of structural units connected to the branch points, and each structural unit may be connected to another branch point and extend in one or more directions to form a three-dimensional structure without crosslinking.

The polymer segment may determine a size of the branched polymer and may be formed into a hyperbranched polymer that occupies a specific expanded space by controlling, for example, the number of branch points and structural units and/or the degree of branching (DB) in the polymer segment.

The branched polymer may be a hyperbranched polymer.

In an embodiment, the number of repeating structural units of the hyperbranched polymer may be three or more, and may be from 3 to 100, 3 to 50, 4 to 30, 5 to 20, or 6 to 10.

The degree of branching of a branched polymer may be calculated from a ratio between the linear structure and the branched structure of the polymer, and may be calculated from Equation 1.

$$Degree of branching ( D B ) = ( D + T ) / ( D + T + L ) \qquad Equation 1$$

In Equation 1, D represents dendrimeric units derived from branch points, T represents terminal units, and L represents linear units.

D, T, and L values may be derived by distinguishing the signals of each structure using nuclear magnetic resonance spectroscopy (NMR) and integrating. The closer the degree of branching (DB) is to 0, the closer it may be to a linear structure, and when the degree of branching (DB) is 1, it may mean a complete branched structure.

Generally, the degree of branching of a hyperbranched polymer may be between about 0.2 and about 1.0. Branching reactions in the branched polymer may occur randomly, and accordingly, the number of branch points and structural units (repeating units) in a polymer segment and/or the degree of branching may vary. These characteristics may lead to structural diversity in the branched polymers, which may affect the physical and chemical properties of the final material, the branched polymer.

The branched polymer may have the following properties. First, the branched polymers include abundant reactive functional groups at the branching end groups. The reactive function groups facilitate various chemical modifications and functionalization. This may allow branched polymers to play an important role in a variety of applications such as drug delivery, catalyst design, coatings, and polymer composites. Second, compared to linear polymers with the same weight average molecular weight, it may exhibit relatively low solution viscosity, which may be advantageous in the mixing and processing of polymer solutions, and this low viscosity may enable cost-effective mass processing. Third, the branched polymers may be endowed with characteristics tailored to specific application purposes through the diversity of branched structures and design flexibility, and may be adjusted to be designed as biocompatible materials or to improve heat resistance and mechanical strength.

The polymer segment may be obtained by polymerization of reactants (monomers) having reactive sites such as, —OH, —NH— and/or —NH₂, and may include structural units (repeating units) derived from glycerol, ethylene glycol, propylene glycol, ethylene imine, piperazine, trimethylolpropane, sorbitol, acrylic acid, methacrylic acid, a derivative thereof, or a combination thereof.

The monomers used to form these polymer segments may be divided into various types depending on their structure and reactivity. For example, an AB₂ type monomer includes one A type functional group and two B type functional groups and may form a branched structure through a selective reaction between A and B. For example, an A₂B₃ type monomer may form a higher degree of branching and complex three-dimensional structure by including two A type functional groups and three B type functional groups. For example, an ABₓ type monomer (x≥3) may include one A functional group and three or more B functional groups, and as the value of x increases, the degree of branching and complexity of the polymer may increase, and for example, it may include multifunctional alcohols such as glycerol.

An example of a monomer having the characteristics of an AB₂ type monomer is glycidol. Glycidol may form a branched structure through ring-opening polymerization (ROP), and may be efficiently polymerized through anionic ring-opening multi-branching polymerization. In this process, the epoxide ring of glycidol may show high reactivity and act simultaneously on branching and growth processes. The glycidol may be widely used in the production of hyperbranched polyether polyols.

Alkylene oxide monomers, such as ethylene oxide or propylene oxide (e.g., as a derivative of ethylene glycol or propylene glycol), may be used to synthesize branched polyethers. Alkylene oxide monomers may serve as important building blocks for designing polymer materials suitable for specific applications by introducing functional terminal groups or through structural control.

These monomers are utilized to design and synthesize multi-branched polymers suitable for specific applications by utilizing their respective reactive functional groups and branched structure forming capabilities.

The hydrophobic unit may be a moiety having hydrophobic properties. The hydrophobic unit may be derived from an initiator for the polymerization of a branched polymer and may be a moiety (e.g., a hydrocarbon moiety) other than a reactive site (e.g., —OH, —NH—, and/or —NH₂) of the initiator. The hydrophobic unit may include a substituted or unsubstituted C1 to C30 alkyl group, a substituted or unsubstituted C3 to C30 cycloalkyl group, a substituted or unsubstituted C2 to C30 alkenyl group, a substituted or unsubstituted C3 to C30 cycloalkenyl group, a substituted or unsubstituted C2 to C30 alkynyl group, a substituted or unsubstituted C6 to C30 aromatic group, a substituted or unsubstituted siloxane group, or a combination thereof, but is not limited thereto.

The hydrophobic unit may be bonded to the starting point of the polymer segment and may be positioned on the opposite side of the hydrophilic functional group described below across the polymer segment. When the initiator has one reaction site, the reaction by the initiator occurs in one direction, and thus the branched polymer may include a polymer segment bonded to one side of the hydrophobic unit. When there are two reaction sites of the initiator, the reaction by the initiator occurs in both directions, and thus the branched polymer may include polymer segments bonded to both sides of the hydrophobic unit. When the initiator has three reaction sites, the reaction by the initiator occurs in three directions, and thus it may include a polymer segment that is bonded in three directions to the hydrophobic units of the branched polymer. Therefore, the size and structure of the branched polymer may be controlled depending on the type of initiator.

The hydrophilic functional group may be positioned at the terminal end of the polymer segment. The hydrophilic functional group may include an anionic functional group, a cationic functional group, a non-ionic functional group, or a combination thereof, and may include a hydroxyl group, a sulfonate group, a carboxylate group, a phosphonate group, an ammonium group, a pyrrolidium group, an imidazolium group, an amino group, an amide group, an aldehyde group, a ketone group, or a combination thereof, but is not limited thereto.

The branched polymer may be a branched polyglycerol derivative (a branched polymer of a glycerol derivative) having one or more structural units (repeating units) derived from glycerol, and the branched polyglycerol derivative may include one or more structural units represented by Chemical Formula A and a terminal portion represented by Chemical Formula B.

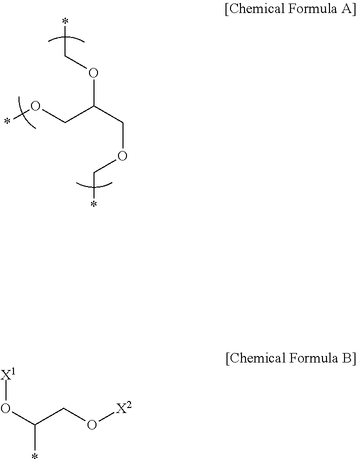

In Chemical Formula A or B,
X¹ and X² may each independently be hydrogen or a hydrophilic functional group, and the hydrophilic functional group may be a sulfonate group, a carboxylate group, a phosphonate group, an ammonium group, a pyrrolidium group, an imidazolium group, an amino group, an amide group, an aldehyde group, a ketone group, an epoxide group, or a combination thereof, and
the symbol “*” may be a linking point to an adjacent structural unit or a terminal moiety.

The branched polyglycerol derivative may be represented by Chemical Formula C, but is not limited thereto.

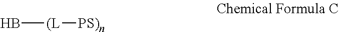

In Chemical Formula C,
HB may be a hydrophobic unit a substituted or unsubstituted C1 to C30 alkyl group, a substituted or unsubstituted C3 to C30 cycloalkyl group, a substituted or unsubstituted C2 to C30 alkenyl group, a substituted or unsubstituted C3 to C30 cycloalkenyl group, a substituted or unsubstituted C2 to C30 alkynyl group, a substituted or unsubstituted C6 to C30 aromatic group, a substituted or unsubstituted siloxane group, or a combination thereof,
n may be a polymer segment including a hydrophilic functional group,
L may be a linking group between a hydrophobic unit and a polymer segment. In an embodiment, L may be a single bond, a substituted or unsubstituted C1 to C10 alkylene group, or a substituted or unsubstituted C1 to C10 oxyalkylene group, and
n may be an integer from 1 to 5, for example, 1 to 4, 1 to 3, or 1 to 2.
   In the branched polyglycerol derivative represented by Chemical Formula C, the polymer segment (PS) may be represented by, for example, the Chemical Formula D, but is not limited thereto.

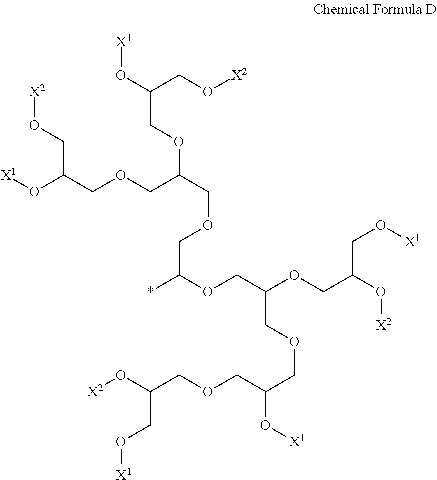

In Chemical Formula D,
X¹ and X² may each independently be hydrogen or a hydrophilic functional group, and the hydrophilic functional group may be a sulfonate group, a carboxylate group, a phosphonate group, an ammonium group, a pyrrolidium group, an imidazolium group, an amino group, an amide group, an aldehyde group, a ketone group, an epoxide group, or a combination thereof, and
the symbol “*” may be a linking point with L.

In Chemical Formula D, an example of a branched polymer including one or more structural units represented by Chemical Formula A that extends and are connected to a plurality of branch points is exemplified, and the number of branch points and structural units (repeating units) may vary and is not limited to the previously described structure.

A number average molecular weight of the branched polymer may be about 200 grams per mole (g/mol) to about 10,000 g/mol, for example, about 300 g/mol to about 9,000 g/mol, about 400 g/mol to about 8,000 g/mol, about 500 g/mol to about 7,000 g/mol, about 600 g/mol to about 6,000 g/mol, about 700 g/mol to about 5,000 g/mol, about 800 g/mol to about 4,000 g/mol, or about 900 g/mol to about 3,000 g/mol. A weight average molecular weight of the branched polymer may be about 200 g/mol to about 10,000 g/mol, for example, about 300 g/mol to about 9,000 g/mol, about 400 g/mol to about 8,000 g/mol, about 500 g/mol to about 7,000 g/mol, about 600 g/mol to about 6,000 g/mol, about 700 g/mol to about 5,000 g/mol, about 800 g/mol to about 4,000 g/mol, about 900 g/mol to about 3,000 g/mol, or about 1,000 g/mol to about 2,000 g/mol. The number average molecular weight and weight average molecular weight may be analyzed through gel permeation chromatography (GPC), which may be performed at a flow rate of about 1.0 mL/min using dimethylformamide (DMF) as a mobile phase at about 25° C. GPC analysis may be performed using an Agilent 1200 Series system and calculations may be performed based on polyethylene glycol (PEG) standards.

The branched polymer may be an amphiphilic polymer including hydrophobic units and hydrophilic functional groups, and thus may form micelles through spontaneous self-assembly of hydrophobic units of adjacent branched polymers in a dispersion medium. The dispersion medium may be water such as deionized water, and the micelle may be colloidal nanoparticles.

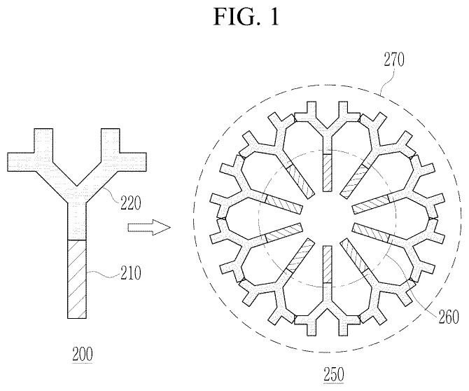

FIG. 1 is a schematic view showing an example of a branched polymer and a micelle thereof according to an embodiment.

Referring to FIG. 1, the micelle 250 may be a three-dimensional nanoparticle in which a plurality of branched polymers 200 is self-assembled, and may be a colloidal nanoparticle dispersed in a dispersion medium (e.g., water). The micelle 250 includes a core 260 in which hydrophobic units 210 of adjacent branched polymers 200 are assembled and arranged inside, and a shell 270 including polymer segments 220 including structural units and hydrophilic functional groups and arranged close to the dispersion medium. The hydrophilic functional groups may be arranged on the outermost surface of the shell 260.

The micelle 250 may be included in the form of colloidal nanoparticles in the polishing slurry, and the particle size of the micelle measured by a dynamic light scattering (DLS) method in an aqueous medium may be less than or equal to about 50 nm, about 1 nm to about 50 nm, about 1 nm to about 40 nm, about 1 nm to about 30 nm, about 1 nm to about 20 nm, about 2 nm to about 50 nm, about 2 nm to about 40 nm, about 2 nm to about 30 nm, about 2 nm to about 20 nm, about 3 nm to about 16 nm, about 4 nm to about 12 nm, about 5 nm to about 10 nm, about 5 nm to about 8 nm.

When a branched polymer is present in a dispersion medium (e.g., water) at a concentration greater than or equal to a predetermined concentration, a micelle may be formed. The branched polymer may be included in an amount of greater than or equal to about 0.1 wt %, or about 0.1 to 30 wt % based on a total amount of the polishing slurry. That is, the polishing slurry may include about 0.1 to about 30 wt % of a branched polymer, a micelle thereof, or a combination thereof, based on the total content of the polishing slurry.

The branched polymer may form a micelle over a predetermined temperature range. In an embodiment, the branched polymer in the polishing slurry may form a micelle at a temperature from room temperature to less than or equal to about 70° C., for example, from room temperature to less than or equal to about 50° C., or from room temperature to less than or equal to about 30° C.

In an embodiment, the branched polymers may form micelles at a predetermined pH range. In an embodiment, the branched polymers may form micelles at pH 2 to 10, for example, 2 to 8, 2 to 6, or 2 to 4.

The branched polymers may be formed into hyperbranched polymers that occupy a space expanded to a predetermined degree by controlling the number and/or degree of branch points and structural units (repeating units), as previously described. In addition, the size and structure of the hyperbranched polymer may be effectively controlled depending on the type of initiator (e.g., the number of reaction sites), and the properties of the branched polymer may be controlled depending on the type and number of hydrophilic functional groups. In addition, the hydrophobic unit and hydrophilic functional group previously described may form a micelle in a dispersion medium (e.g., water), and such a micelle may exist in the form of a colloidal nanoparticle to provide enhanced physical force to the polishing slurry.

Therefore, the polishing slurry including the branched polymer and/or its micelle may be applied to a solid surface covered with a polishing material to effectively remove the polishing material, and chemical mechanical polishing (CMP) may be performed without inorganic abrasives such as silica, ceria, alumina, zirconia, titania, silicon nitride, SiC, or diamond.

In an embodiment, the polishing slurry may be an abrasive-free slurry, thereby effectively reducing or preventing defects such as scratches caused by inorganic abrasives and/or damage caused by inorganic abrasive residues. In an embodiment, the polishing slurry excludes inorganic abrasives. However, the present disclosure is not limited thereto, and the polishing slurry does not exclude further inclusion of an inorganic abrasive.

In addition, the branched polymer and/or the micelle thereof may selectively polish a desired film material by functionalizing them with various functional groups, thereby effectively controlling the polishing selectivity between a film material desired to be removed and a film material not desired to be removed.

The polishing slurry may further include an oxidizing agent. The oxidizing agent may oxidize an object to be polished. For example, when applying the polishing slurry to the object to be polished including a metal or a semi-metal, the surface of the object to be polished may be oxidized to form a metal oxide or a semi-metal oxide. The object to be polished (e.g., a metal oxide or a semi-metal oxide) oxidized by the oxidizing agent may have a relatively lower hardness or be brittle than the metal or semi-metal, and may be effectively removed by the branched polymer and/or the micelle thereof due to the difference in mechanical strength between the object to be polished and the oxidized object to be polished.

The oxidizing agent, provided that it is capable of oxidizing the object to be polished, and may include but is not limited to, hydrogen peroxide, peracetic acid, percarbonates, urea peroxide, perchloride acid, persulfates, iron (III) nitrate, a hydrate thereof, or a combination thereof.

The oxidizing agent may be included in an amount of less than or equal to about 5 wt %, about 0.001 wt % to about 5 wt %, about 0.001 wt % to about 4 wt %, about 0.001 wt % to about 3 wt %, about 0.001 wt % to about 2 wt %, about 0.001 wt % to about 1 wt %, or about 0.001 wt % to about 0.5 wt % based on the polishing slurry.

The polishing slurry may further include an additive such as a chelating agent (oxidation regulator), a surfactant, a dispersant, a pH regulator, a polishing inhibitor, or a combination thereof.

The chelating agent (oxidation regulator) may be phosphoric acid, nitric acid, citric acid, malonic acid, salts thereof, or a combination thereof, but is not limited thereto.

The surfactant may be an ionic or nonionic surfactant, and may be a copolymer of ethylene oxide, a copolymer of propylene oxide, an amine compound, or a combination thereof, but is not limited thereto.

The pH regulator may adjust the pH of the polishing slurry and may be an inorganic acid or a salt thereof, an inorganic base, an organic acid or a salt thereof, or a combination thereof. The inorganic acid or a salt thereof may include nitric acid, hydrochloric acid, phosphoric acid, sulfuric acid, hydrofluoric acid, hydrobromic acid, iodic acid, or a salt thereof; the inorganic base may include potassium hydroxide, sodium hydroxide, or ammonium hydroxide; and the organic acid or a salt thereof may include, formic acid, malonic acid, maleic acid, oxalic acid, adipic acid, citric acid, acetic acid, propionic acid, fumaric acid, lactic acid, salicylic acid, benzoic acid, succinic acid, phthalic acid, butyric acid, glutaric acid, glutamic acid, glycolic acid, lactic acid, aspartic acid, tartaric acid, or a salt thereof, but is not limited thereto.

Each component of the additive may each independently be included in trace amounts, for example, from about 1 ppm to about 100,000 ppm, but is not limited thereto.

The polishing slurry may further include a dispersion medium capable of dissolving and/or dispersing the previously-described components, and the dispersion medium may be water. In an embodiment, the water may be distilled water and/or deionized water. The dispersion medium may be included as a balance amount excluding solids such as the branched polymer, a micelle of the branched polymers, an oxidizing agent, and various additives.

The pH of the polishing slurry may be about 2.0 to about 12.0, about 2.0 to about 10.0, about 2.0 to about 8.0, about 2.0 to about 6.0, or about 2.0 to about 4.0.

The polishing slurry may be applied in the formation of various structures. In an embodiment, the polishing slurry may be applied in the polishing process of a conductive layer such as a metal wire, or a dielectric layer such as a shallow trench isolation (STI) or an insulating film. The polishing slurry may be used to polish a conductive layer such as a metal wire in a semiconductor substrate, or may be used to polish a metal layer such as tungsten (W) or a tungsten alloy.

An example of a method of manufacturing a semiconductor device using the polishing slurry is described below.

A method of manufacturing a semiconductor device according to some example embodiments includes performing chemical mechanical polishing (CMP) on a surface of an object to be polished.

The object to be polished may include a variety of structures, for example, a semiconductor substrate such as a silicon wafer (including a thin film such as a dielectric layer or a metal layer). The polishing surface may include a metal such as tungsten, molybdenum, aluminum, copper or nickel, an alloy thereof, or a metal oxide or semi-metal oxide generated during a chemical-mechanical polishing process; an oxide such as silicon oxide, aluminum oxide, titanium oxide, gallium oxide, tungsten oxide, or molybdenum oxide; a nitride such as silicon nitride, aluminum nitride, titanium nitride or gallium nitride; a carbide such as silicon carbide; an elemental semiconductor such as silicon or germanium; a compound semiconductor such as InP, GaAs; an organic or inorganic compound such as tetraethyl orthosilicate (TEOS); or a combination thereof.

In an embodiment, the polishing slurry may be used to polish a conductive layer such as a metal wire within a semiconductor substrate, and may be used to form a conductive pattern (e.g., a conductive wire) from a conductive layer including tungsten (W) or an alloy thereof. The conductive pattern may be embedded in a trench of the dielectric layer.

An embodiment of a method of manufacturing a semiconductor device using the polishing slurry is described.

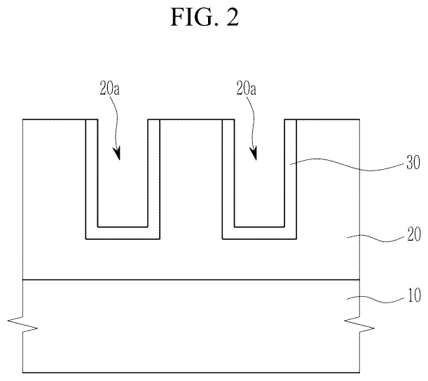

FIGS. 2 to 5 are cross-sectional views showing an example of a method of manufacturing a semiconductor device according to some example embodiments.

Referring to FIG. 2, a dielectric layer 20 is formed on a semiconductor substrate 10. The dielectric layer 20 may include oxide, nitride and/or oxynitride. Then, the dielectric layer 20 is etched to form a trench 20a. The width of the trench 20a may be less than about 50 nm, greater than or equal to about 1 nm and less than about 50 nm, about 1 nm to about 40 nm, about 1 nm to about 30 nm, about 1 nm to about 20 nm, about 1 nm to about 15 nm, about 1 nm to about 10 nm, or about 1 nm to about 8 nm. Then, a barrier layer 30 is formed on the side wall of the trench 20a. The barrier layer 30 may include Ti, Ta, TiN, and/or TaN, but is not limited thereto.

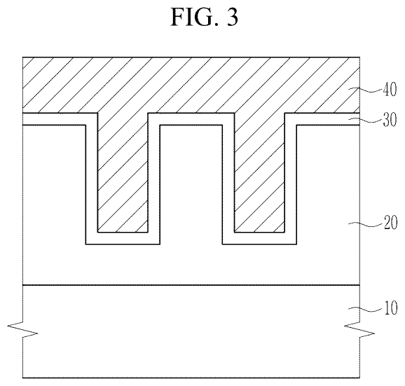

Referring to FIG. 3, a conductive layer 40 is formed inside and on the trench 20a. The conductive layer 40 may include tungsten, molybdenum, aluminum, copper, nickel, an alloy thereof, or a combination thereof.

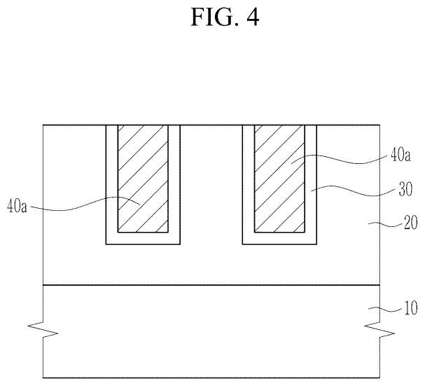

Referring to FIG. 4, the surface of the conductive layer 40 is planarized to substantially match the surface of the dielectric layer 20 to form an embedded conductive pattern 40a. The planarization may be performed by chemical mechanical polishing using a chemical mechanical polishing equipment, and the polishing slurry may be used. This will be described later.

In an embodiment, when the conductive layer 40 is a tungsten-containing layer, the removal rate (RR) of the tungsten-containing wire of the polishing slurry may be greater than or equal to about 300 Å/min, about 300 Å/min to about 5,000 Å/min, about 400 Å/min to about 5,000 Å/min, about 500 Å/min to about 5,000 Å/min, about 600 Å/min to about 5,000 Å/min, about 700 Å/min to about 5,000 Å/min, about 800 Å/min to about 5,000 Å/min, about 800 Å/min to about 4,000 Å/min, about 800 Å/min to about 3,000 Å/min, about 800 Å/min to about 2,000 Å/min, about 800 Å/min to about 1,500 Å/min, or about 800 Å/min to about 1,200 Å/min.

The polishing slurry may have a high polishing selectivity between a conductive material such as a metal and a dielectric material such as an oxide, and thus may effectively polish a conductive layer such as a metal at a high polishing rate while reducing loss or damage to the dielectric layer. In an embodiment, when the dielectric layer 20 is an oxide layer (e.g., a silicon oxide layer) and the conductive layer 40 is a tungsten-containing layer, the ratio of the polishing rate of the tungsten to the polishing rate of the oxide (e.g., silicon oxide) of the polishing slurry, i.e., the polishing selectivity, is better as it is higher.

In an embodiment, the polishing selectivity may be higher than about 200:1, the polishing selectivity may be higher than about 300:1, higher than about 400:1, higher than about 500:1, higher than about 600:1, higher than about 700:1, higher than about 800:1. The polishing selectivity may be higher than about 200:1 and lower than about 5000:1, higher than about 300:1 and lower than about 5000:1, higher than about 400:1 and lower than about 5000:1, higher than about 500:1 and lower than about 5000:1, higher than about 600:1 and lower than about 5000:1, higher than about 700:1 and lower than about 5000:1, higher than about 800:1 and lower than about 5000:1, higher than about 800:1 and lower than about 4000:1, higher than about 800:1 and lower than about 3000:1, higher than about 800:1 and lower than about 2000:1, higher than about 800:1 and lower than about 1500:1, or higher than about 800:1 and lower than about 1200:1.

In an embodiment, the oxidizing agent of the polishing slurry may oxidize the polishing surface (e.g., a metal layer such as tungsten) to form a metal oxide (e.g., tungsten oxide) at a predetermined thickness on the polishing surface, and in the performing of the polishing, the branched polymer and/or micelle thereof may perform polishing by physically and/or chemically removing the metal oxide on the polishing surface. In this way, the polishing slurry may effectively remove the polishing surface without an inorganic abrasive such as silica, and may effectively prevent defects such as scratches on the polished surface caused by the inorganic abrasive and damage caused by the residue of the inorganic abrasive.

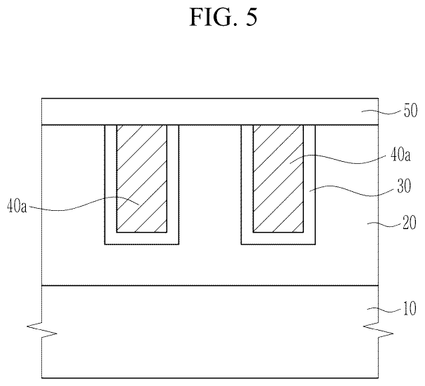

Referring to FIG. 5, a capping layer 50 is formed on the embedded conductive pattern 40a and the dielectric layer 20. The capping layer 50 may include SiN and/or SiC, but is not limited thereto.

Hereinafter, the planarization for forming the embedded conductive pattern 40a is described. The planarization may be performed by chemical mechanical polishing (CMP) using chemical mechanical polishing (CMP) equipment as previously described.

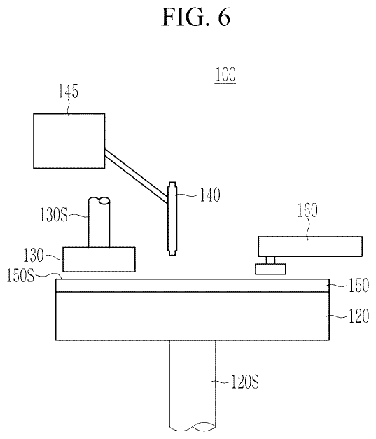

FIG. 6 is a schematic view showing a chemical mechanical polishing equipment according to an embodiment.

Referring to FIG. 6, a chemical mechanical polishing equipment 100 according to an example may include a lower base (not shown); a platen 120 rotatably provided on an upper surface of the lower base; a polishing head 130; a polishing pad 150 on the platen 120; a pad conditioner 160; and at least one polishing slurry supply device 140 disposed adjacent to the polishing pad 150 to supply polishing slurry to the polishing pad 150.

The platen 120 may be provided rotatable on the surface of the lower base. In an embodiment, the platen 120 may receive rotational power from a motor (not shown) disposed within the lower base, and accordingly may rotate in a certain direction, such as clockwise or counterclockwise, by a rotation axis 120S perpendicular to the surface of the platen 120.

The polishing head 130 may be disposed on the platen 120 and may hold a body to be polished. The body to be polished may be a semiconductor substrate 10, such as a silicon wafer, and the semiconductor substrate 10 may be covered with a dielectric layer 20 having a trench 20a and a metal layer 40 as previously described. The polishing head 130 may include a rotating shaft 130S that rotates the body to be polished. When performing polishing, the rotation direction of the polishing head 130 may be opposite to the rotation direction of the platen 120.

The polishing pad 150 may be disposed on the platen 120 so as to be supported by the platen 120. The polishing pad 150 may rotate together with the platen 120. The polishing pad 150 may have a roughly formed polishing surface 150S. This polishing surface 150S may mechanically polish the surface of the semiconductor substrate 10 by directly contacting the semiconductor substrate 10. The polishing pad 150 may be made of a porous material having a plurality of microspaces, and the plurality of microspaces may accommodate polishing slurry. The polishing surface 150S of the polishing pad 150 may include a surface that directly contacts the body to be polished and a predetermined depth therefrom, and the predetermined depth may be about 10% to about 100%, about 20% to about 100%, about 30% to about 100%, about 40% to about 100%, or about 50% to about 100% of the thickness of the polishing pad 150. The polishing surface 150S of the polishing pad 150 may be flat, for example. The polishing surface 150S of the polishing pad 150 may have, for example, protrusions or grooves.

A pad conditioner 160 may be adjacent to the polishing pad 150 and may maintain the state of the polishing surface 150S so that the surface of the semiconductor substrate 10 may be effectively polished while the polishing process is performed.

The polishing slurry supply device 140 may be adjacent to the polishing pad 150 and may supply polishing slurry from the polishing slurry tank 145 and supply the polishing slurry to the polishing pad 150. The polishing slurry supply device 140 may include a nozzle capable of supplying polishing slurry onto the polishing pad 150 during the polishing process. The polishing slurry supply device 140 may supply the polishing slurry.

Chemical mechanical polishing may be performed, for example, by disposing a semiconductor substrate 10 and a polishing pad 150 so as to face each other, supplying the polishing slurry from a polishing slurry supply device 140 between the semiconductor substrate 10 and the polishing pad 150, and performing polishing by bringing the surface of the semiconductor substrate 10 and the polishing pad 150 into contact.

For example, the supplying of the polishing slurry may be performed at a rate of, for example, about 10 mL/min (milliliter per minute) to about 300 mL/min.

The performing of polishing may be performed by mechanical friction by bringing the surface of the semiconductor substrate 10 into contact with the polishing pad 150 and rotating it. For example, a pressure of about 1 psi to about 5 psi may be applied during the polishing.

Although a method of manufacturing a semiconductor device according to an embodiment is previously described, it is not limited thereto and may be applied to semiconductor devices with various structures.

Hereinafter, the embodiments are illustrated in more detail with reference to examples. However, these examples are exemplary, and the scope of claims is not limited thereto.

### Synthesis Example: Synthesis of Branched Polymers

### Synthesis Example 1

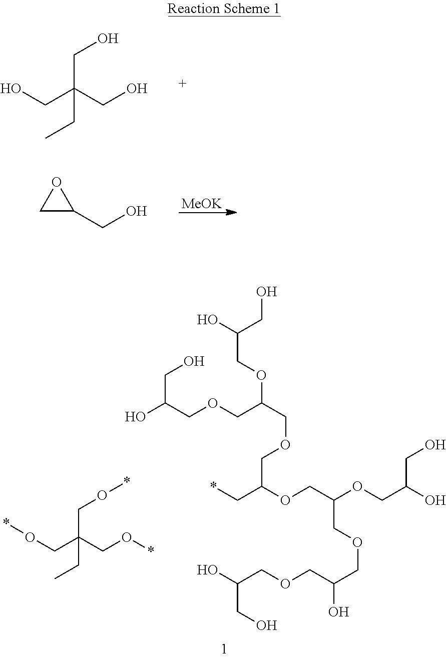

Potassium methoxide (2.185 g, 31.15 mmol) is added to a methanol solution of 1,1,1-tris(hydroxymethyl) propane (4.18 g, 31.15 mmol) and stirred for 2 hours to activate the initiator and prepare an initiator solution. Next, the initiator solution is heated to 40° C. and vacuum distilled. Toluene is injected into the initiator from which methanol has been removed and reduced pressure azeotropic distillation is performed twice. Dry NMP (10 mL, 1 mL per 3 g of glycidol) is added thereto and stirred to prepare an initiator solution. Glycidol (30 g, 405 mmol) is added dropwise to the initiator solution heated to 80° C. for 24 hours and stirred for an additional 12 hours to perform polymerization. Next, the polymer solution is cooled to room temperature, the reaction is stopped with an excess of methanol, and precipitation is performed twice in cold diethyl ether. The product recovered after precipitation is dissolved in methanol and then treated twice using Amberlite IR-120 (H) ion exchange resin. Afterwards, the polymer solution is vacuum distilled to remove methanol, and a pale-yellow transparent Polymer 1 is obtained.

In reaction Scheme 1, the structure of Polymer 1 should be understood
as: each * in

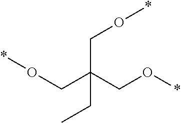 [SMILES: *OCC(CC)(CO*)CO*]

is connected to one

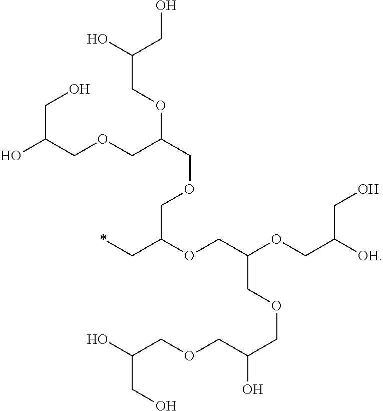 [SMILES: *CC(COCC(COCC(O)CO)OCC(O)CO)OCC(COCC(O)COCC(O)CO)OCC(O)CO]

A number average molecular weight (Mn), a weight average molecular weight (Mw), and polydispersity index (PDI) of Polymer 1 are 970, 1320, and 1.38, respectively.

¹H NMR (400 MHZ, D₂O) δ 4.07-3.35 (m, 222H), 1.41-1.25 (m, 6H), 0.83 (d, J=7.1 Hz, 9H).

MALDI-ToF: [M+Na]⁺: 675.5

### Synthesis Example 2

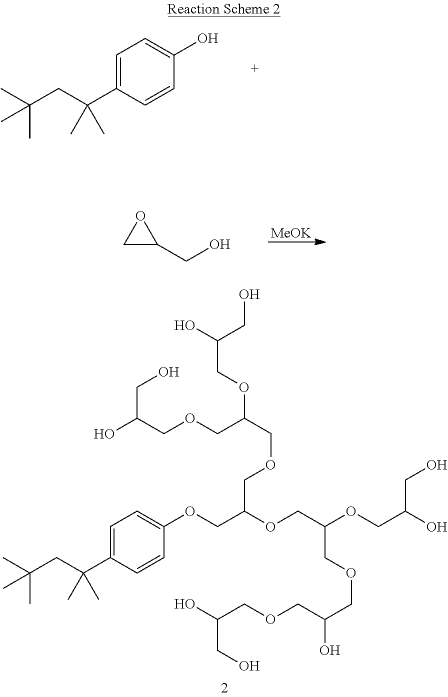 [SMILES: "MeOK" ; CC(C)(C)CC(C)(C)c1ccc(O)cc1 ; OCC1CO1 ; CC(C)(C)CC(C)(C)c1ccc(OCC(COCC(COCC(O)CO)OCC(O)CO)OCC(COCC(O)COCC(O)CO)OCC(O)CO)cc1]

Potassium methoxide (2.185 g, 31.15 mmol) is added to a methanol solution of 4-t-octylphenol (6.428 g, 31.15 mmol) and stirred for 2 hours to activate the initiator and prepare an initiator solution. Next, the initiator solution is heated to 40° C. and vacuum distilled. Toluene is injected into the initiator from which methanol has been removed and reduced pressure azeotropic distillation is performed twice. Dry NMP (10 mL, 1 mL per 3 g of glycidol) is added thereto and stirred to prepare an initiator solution. Glycidol (30 g, 405 mmol) is added dropwise to the initiator solution heated to 80° C. for 24 hours and stirred for an additional 12 hours to perform polymerization. Next, the polymer solution is cooled to room temperature, the reaction is stopped with an excess of methanol, and precipitation is performed twice in cold diethyl ether. The product recovered after precipitation is dissolved in methanol and then treated twice using Amberlite IR-120(H) ion exchange resin. Afterwards, the polymer solution is vacuum distilled to remove methanol, and a pale-yellow transparent Polymer 2 is obtained.

A number average molecular weight (Mn), a weight average molecular weight (Mw), and polydispersity index (PDI) of Polymer 2 are 760, 1040, and 1.37, respectively.

¹H NMR (300 MHZ, D₂O) δ 7.45 (d, J=8.7 Hz, 2H), 6.98 (d, 8.1 Hz, 2H), 4.34-3.42 (m, 97H), 1.75 (s, 2H), 1.31 (s, 6H) 0.71 (s, 9H).

MALDI-ToF: [M+Na]+: 673.5

### Synthesis Example 3

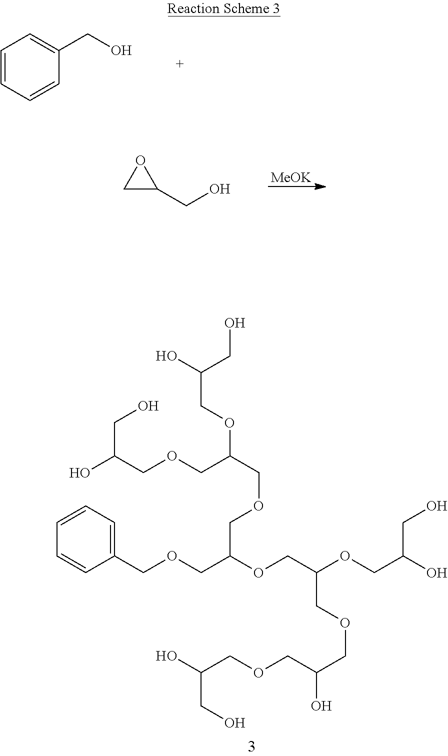 [SMILES: "MeOK" ; OCc1ccccc1 ; OCC1CO1 ; OCC(O)COCC(O)COCC(COC(COCc1ccccc1)COCC(COCC(O)CO)OCC(O)CO)OCC(O)CO]

Potassium methoxide (2.185 g, 31.15 mmol) is added to a methanol solution of benzyl alcohol (3.37 g, 31.15 mmol) and stirred for 2 hours to activate the initiator and prepare an initiator solution. Next, the initiator solution is heated to 40° C. and vacuum distilled. Toluene is injected into the initiator from which methanol has been removed and reduced pressure azeotropic distillation is performed twice. Dry NMP (10 mL, 1 mL per 3 g of glycidol) is added thereto and stirred to prepare an initiator solution. Glycidol (30 g, 405 mmol) is added dropwise to the initiator solution heated to 80° C. for 24 hours and stirred for an additional 12 hours to perform polymerization. Next, the polymer solution is cooled to room temperature, and the reaction is stopped with an excess amount of methanol. Precipitation is carried out twice in cold diethyl ether. The product recovered after precipitation is dissolved in methanol and then treated twice using Amberlite IR-120 (H) ion exchange resin. Afterwards, the polymer solution is vacuum distilled to remove methanol, and a pale-yellow transparent Polymer 3 is obtained.

A number average molecular weight (Mn), a weight average molecular weight (Mw), and polydispersity index (PDI) of Polymer 3 are 520, 720, and 1.38, respectively.

¹H NMR (400 MHZ, D₂O) δ 7.35 (q, J=5.9, 5.0 Hz, 5H), 4.52 (s, 2H), 4.07-3.32 (m, 167H).

MALDI-ToF: [M+Na]⁺: 649.4

### Synthesis Example 4

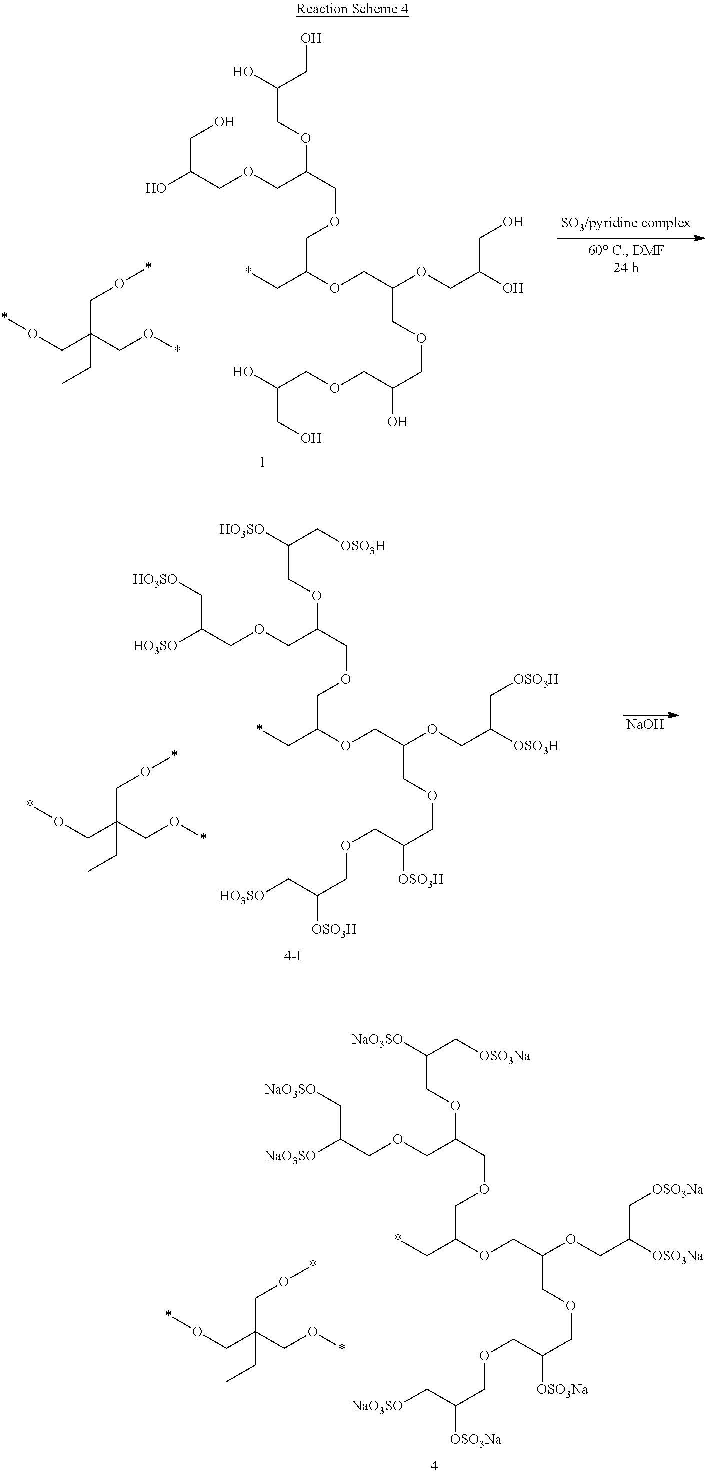

17.6 g (197.7 mmol of OH groups) of Polymer 1 obtained in Synthesis Example 1 is dissolved in 176 mL of DMF, and 47.2 g (296.7 mmol) of SO₃/pyridine composite is added while stirring at 60° C., and then the mixture is stirred for 24 hours to obtain Polymer 4-1. Next, 50 mL of distilled water is added thereto and then 1 M NaOH solution is added thereto until the pH reaches 9 to prepare a polymer solution. Next, the polymer solution is purified by dialysis against a saturated NaCl solution for 2 days and against distilled water for 2 days. Finally, the purified polymer solution is concentrated under reduced pressure and freeze-dried to obtain Polymer 4 as a pale-yellow solid.

A number average molecular weight of Polymer 4 is 2,570.

¹H NMR (400 MHZ, D₂O) δ 4.45-3.35 (m, 196H), 1.47 (dt, J=15.3, 8.0 Hz, 6H), 0.93 (s, 9H).

### Synthesis Example 5

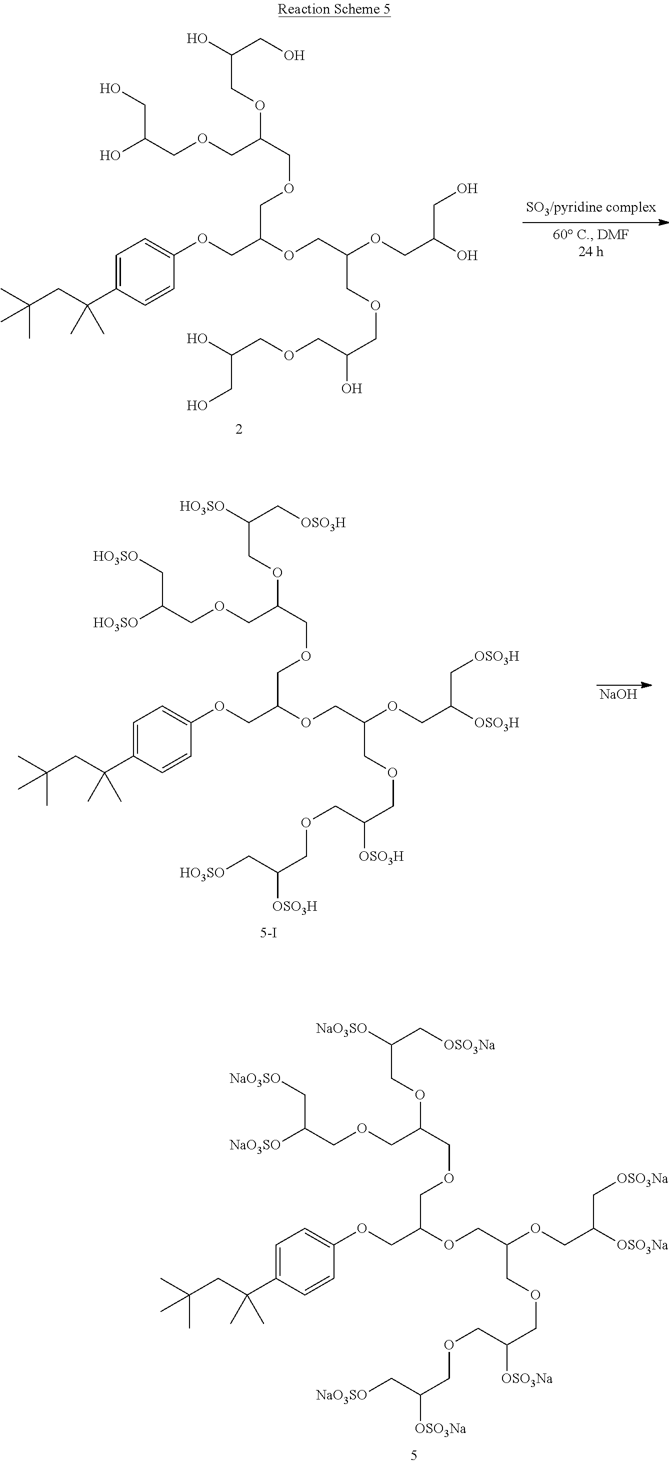

17.0 g (159.3 mmol of OH groups) of Polymer 2 obtained in Synthesis Example 2 is dissolved in 170 mL of DMF, and 38 g (239 mmol) of SO₃/pyridine composite is added while stirring at 60° C., and then the mixture is stirred for 24 hours to obtain Polymer 5-1. Next, 50 mL of distilled water is added to Polymer 5-I and then 1 M NaOH solution is added thereto until the pH reaches 9 to prepare a polymer solution. Next, the polymer solution is purified by dialysis against a saturated NaCl solution for 2 days and against distilled water for 2 days. Finally, the purified polymer solution is concentrated under reduced pressure and freeze-dried to obtain Polymer 5 as a pale-yellow solid.

A number average molecular weight of Polymer 5 is 3,100.

¹H NMR (400 MHZ, D₂O) δ 7.50 (d, J=8.2 Hz, 2H), 7.04 (d, J=8.2 Hz, 2H), 4.43-3.36 (m, 128H), 1.78 (s, 2H), 1.38 (s, 6H), 0.73 (d, J=5.5 Hz, 9H).

### Synthesis Example 6

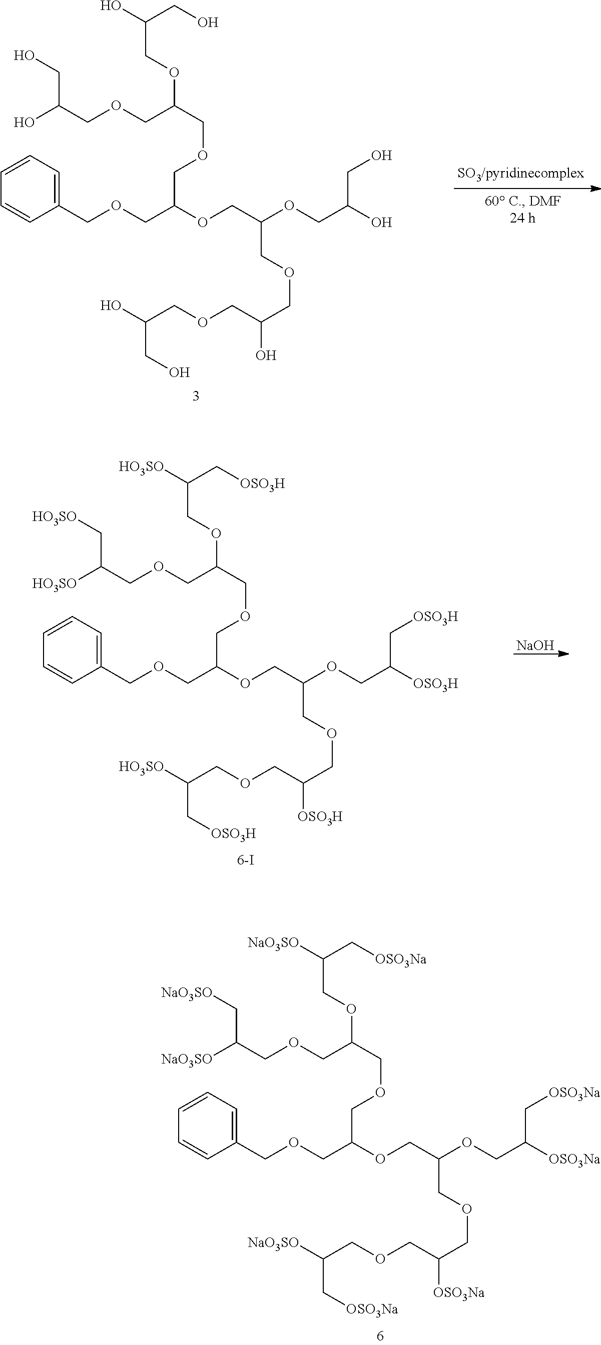

13.0 g (145 mmol of OH groups) of Polymer 3 obtained in Synthesis Example 3 is dissolved in 130 mL of DMF, and 34.6 g (218 mmol) of SO₃/pyridine composite is added while stirring at 60° C., and then the mixture is stirred for 24 hours to obtain Polymer 6-1. Next, 50 mL of distilled water is added to Polymer 6-I and then 1 M NaOH solution is added thereto until the pH reaches 9 to prepare a polymer solution. Next, the polymer solution is purified by dialysis against a saturated NaCl solution for 2 days and against distilled water for 2 days. Finally, the purified polymer solution is concentrated under reduced pressure and freeze-dried to obtain Polymer 6 as a pale-yellow solid.

A number average molecular weight of Polymer 6 is 5,820.

1H NMR (400 MHZ, D₂O) δ 7.41 (s, 5H), 4.67-3.44 (m, 274H).

### Synthesis Example 7

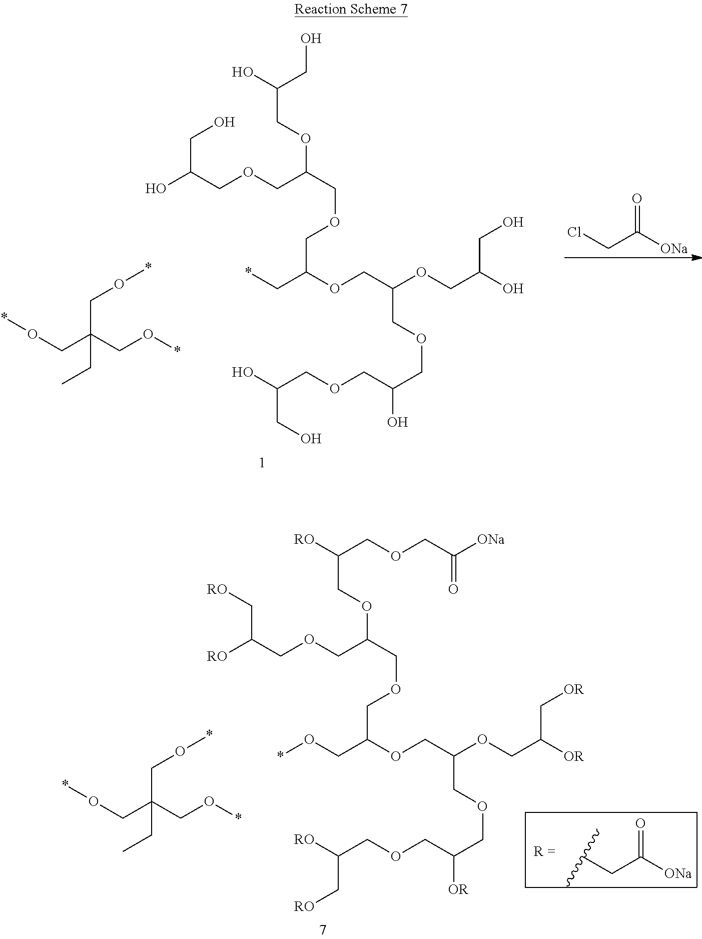

A solution of 108.5 g (931.5 mmol) of sodium chloroacetate dissolved in 130 mL of distilled water is slowly added to a mixed solution of 27.6 g (310.5 mmol of OH groups) of Polymer 1 obtained in Synthesis Example 1 and 124.2 g (931.5 mmol of NaOH) of 30 wt % NaOH over 30 minutes. Then, the reaction mixture is heated to 80° C. and reacted for 16 hours, cooled to room temperature, neutralized with 2N hydrochloric acid, and concentrated under reduced pressure. The reaction product is then purified by dialysis against distilled water. Finally, the purified solution is concentrated under reduced pressure and freeze-dried to obtain Polymer 7 as a colorless solid.

A number average molecular weight of Polymer 7 is 2,110.

¹H NMR (400 MHZ, D₂O) δ 4.24-3.32 (m, 132H), 1.35 (s, 2H), 0.85 (s, 3H).

### Synthesis Example 8

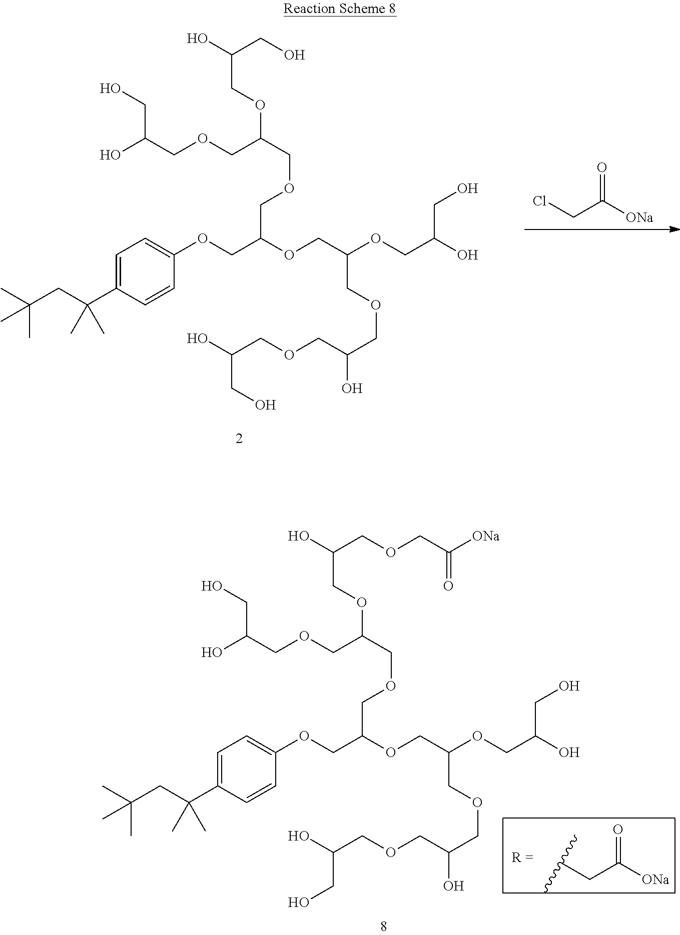

A solution of 108.5 g (931.5 mmol) of sodium chloroacetate dissolved in 130 mL of distilled water is slowly added to a mixed solution of 23.0 g (310.5 mmol of OH groups) of Polymer 2 obtained in Synthesis Example 2 and 124.2 g (931.5 mmol of NaOH) of 30 wt % NaOH over 30 minutes. Then, the reaction mixture is heated to 80° C. and reacted for 16 hours, cooled to room temperature, neutralized with 2N hydrochloric acid, and concentrated under reduced pressure. The reaction product is then purified by dialysis against distilled water. Finally, the purified solution is concentrated under reduced pressure and freeze-dried to obtain Polymer 8 as a colorless solid.

A number average molecular weight of Polymer 8 is 2,580.

¹H NMR (400 MHZ, D₂O) δ 7.44 (d, J=8.4 Hz, 2H), 6.97 (d, J=7.9 Hz, 2H), 4.21-3.41 (m, 128H), 1.73 (s, 2H), 1.33 (s, 6H), 0.75-0.61 (m, 9H).

### Synthesis Example 9

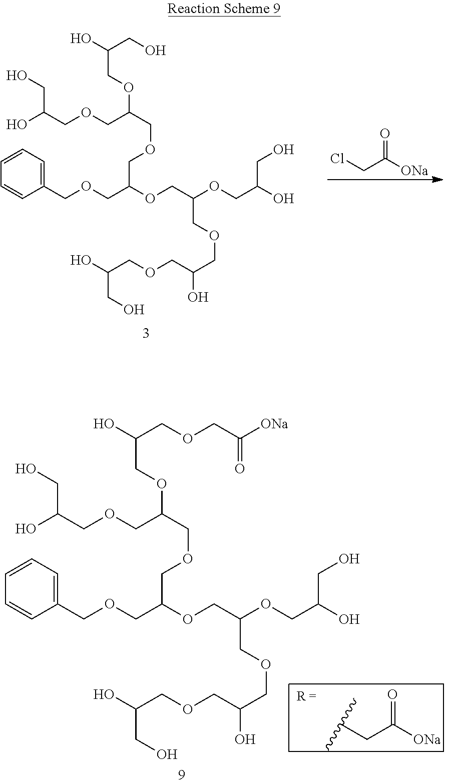

A solution of 108.5 g (931.5 mmol) of sodium chloroacetate dissolved in 130 mL of distilled water is slowly added to a mixed solution of 27.8 g (310.5 mmol of OH groups) of Polymer 3 obtained in Synthesis Example 3 and 124.2 g (931.5 mmol of NaOH) of 30 wt % NaOH over 30 minutes. Then, the reaction mixture is heated to 80° C. and reacted for 16 hours, cooled to room temperature, neutralized with 2N hydrochloric acid, and concentrated under reduced pressure. The reaction product is then purified by dialysis against distilled water. Finally, the purified solution is concentrated under reduced pressure and freeze-dried to obtain Polymer 9 as a colorless solid.

A number average molecular weight of Polymer 9 is 4,410.

¹H NMR (400 MHZ, D₂O) δ 7.46 (s, 5H), 4.63 (s, 2H), 4.12-3.48 (m, 260H).

### Evaluation I: Evaluation of Micelle Formation

Slurries including polymers according to Synthesis Examples are prepared and the formation of micelles is evaluated.

The polymer according to Synthesis Example 2 is stirred at 70° C. for 4 hours and then stirred at room temperature for an additional 24 hours or more. Then, the resultant material is diluted with deionized water to concentrations of 1 wt %, 2.5 wt %, 5 wt %, and 25 wt %, stirred for 30 minutes, and filtered to prepare slurries.

The particle size and distribution of the micelles measured by a dynamic light scattering (DLS) method are recorded in Table 1.

TABLE 1

| Concentration | ID (nm) | ND (nm) | VD (nm) | Z-average (nm) | PDI |
|---|---|---|---|---|---|
| 1 wt % | 6.15 ± 0.12 | 3.54 ± 0.26 | 4.40 ± 0.20 | 5.93 | 0.06 |
| 2.5 wt % | 6.32 ± 0.25 | 3.47 ± 0.16 | 4.37 ± 0.08 | 5.68 | 0.02 |
| 5 wt % | 6.41 ± 0.07 | 3.71 ± 0.18 | 4.62 ± 0.13 | 5.69 | 0.01 |
| 25 wt % | 10.2 ± 0.33 | 2.05 ± 0.18 | 3.04 ± 0.19 | 7.01 | 0.02 |

ID: Intensity distribution
ND: Number distribution
VD: volume distribution

Z-average: Z-average size
PDI: polydispersity index

The intensity distribution (ID) is a particle size distribution that is weighted according to the scattering intensity of each particle, and the average particle size calculated accordingly is the intensity average size.

The number distribution (ND) is a particle size distribution that is weighted according to the number of each particle, and the average particle size calculated accordingly is the number average size.

The volume distribution (VD) is a particle size distribution that calculates the volume of particles according to Mie theory based on the intensity distribution and is weighted accordingly, and the average particle size calculated accordingly is the volume average size.

The Z-average size (Z-average) is the average particle size obtained through cumulative analysis of the intensity distribution and may be defined according to the ISO 22412 method. The Z-average size may be particle size according to a dynamic light scattering (DLS) method.

The polydispersity index (PDI) is an index that indicates how uniformly particles are distributed. In general, the closer the PDI is to 0, the more uniform the particle distribution is.

Referring to Table 1, the slurries included micelles in the form of particles of several nanometers in size formed, which are formed from the polymer according to Synthesis Example. The particle size distribution of the micelles in the slurry is relatively uniform. It is noted that the micelle size may be controlled depending on the polymer concentration.

### Preparation Example: Preparation of Polishing Slurry

### Preparation Example 1

1.5 wt % of Polymer 7 obtained in Synthesis Example 7, 2.4 wt % of hydrogen peroxide (oxidizing agent 1), 0.0104 wt % of Fe(NO₃)₃·9H₂O (oxidizing agent 2), 0.08 wt % of malonic acid (oxidation regulator), nitric acid (pH regulator), and a balance amount of deionized water are mixed to prepare a polishing slurry with a pH of 3.

### Preparation Example 2

A polishing slurry is prepared in the same manner as in Preparation Example 1, except that Polymer 8 obtained in Synthesis Example 8 is used instead of Polymer 7 obtained in Synthesis Example 7.

### Preparation Example 3

A polishing slurry is prepared in the same manner as in Preparation Example 1, except that Polymer 5 obtained in Synthesis Example 5 is used instead of Polymer 7 obtained in Synthesis Example 7.

### EXAMPLES

### Example 1

Chemical mechanical polishing (CMP) is performed under the following conditions.
(1) CMP equipment: GnP tech POLY762 (G&P Technology, Inc.)
(2) Object to be polished: Tungsten layer (3,000 Å-thick tungsten layer on a 12-inch silicon wafer covered with silicon oxide (dielectric) with a plurality of trenches with 200 nm width)
(3) Polishing head rotation speed: 121 rpm
(4) Polishing pad rotation speed: 119 rpm
(5) Applied pressure: 3.0 psi
(6) Initial temperature: 24° C.
(7) Polishing slurry: Polishing slurry according to Preparation Example 1
(8) Polishing slurry supply flow rate: 180 sccm
(9) Polishing time: 60 seconds

### Example 2

Chemical mechanical polishing is performed in the same manner as in Example 1, except that the polishing slurry according to Preparation Example 2 is used instead of the polishing slurry according to Preparation Example 1.

### Example 3

Chemical mechanical polishing is performed in the same manner as in Example 1, except that the polishing slurry according to Preparation Example 3 is used instead of the polishing slurry according to Preparation Example 1.

### Example 4

Chemical mechanical polishing is performed in the same manner as in Example 1, except that the polishing time is increased to more than 60 seconds until the pattern portion (silicon oxide) is exposed.

### Reference Example 1

Chemical mechanical polishing is performed in the same manner as in Example 1, except that a silica-containing slurry (Samsung SDI) is used instead of the polishing slurry according to Preparation Example 1.

### Evaluation II

The polishing performance of chemical mechanical polishing according to Examples and Reference Examples is evaluated.

Polishing performance is evaluated by polishing rate (RR) and polishing selectivity.

The polishing rate (RR) is calculated using Equation 2.

$$Polishing rate ( RR , Å / min ) = ( Initial film thickness ( Å ) - Film thickness after polishing ( Å ) ) / Polishing time ( min ) \qquad Equation 2$$

In Equation 2, the thickness (film thickness) of the tungsten layer may be calculated according to Equation 3, and the volume resistivity and surface resistivity in Equation 3 may be measured with a resistance meter (KLA Tencor, model RS-100) using the DC 4-probe method.

$$Film thickness ( Å ) = [ Volume resistivity ( Ω m ) \div Sheet resistance ( Ω ) ] \times {10}^{10} \qquad Equation 3$$

In Equation 2, the film thickness may be measured using the reflectometry and may be measured with a film thickness measuring device (Filmetrics, model F20).

The polishing selectivity is the ratio of the polishing rate of the tungsten layer to the polishing rate of the oxide (silicon oxide) layer.

The results are recorded in Table 2.

TABLE 2

| | RR₁ (Å/min) | RR₂ (Å/min) | RR₁/RR₂ |
|---|---|---|---|
| Example 1 | 805 | 0-1 | 805:1 |
| Example 2 | 1156 | 0-1 | 1156:1 |
| Example 3 | 1194 | 0-1 | 1194:1 |
| Reference Example 1 | 3397 | 50 | 67.8:1 |

RR₁: Polishing rate of tungsten layer
RR₂: Polishing rate of oxide layer
RR₁/RR₂: Polishing selectivity

Referring to Table 2, the polishing slurries used in Examples exhibit a good polishing rate while having a high polishing selectivity of tungsten/oxide compared to the polishing slurry used in Reference Example. The polishing slurries used in Examples indicate a good level of polishing rate by the polymer and/or micelle without an inorganic abrasive, while improving the polishing selectivity compared to the polishing slurry including an inorganic abrasive.

### Evaluation III

The polished products of chemical mechanical polishing (CMP) according to Examples and Reference Example are evaluated.

The polishing rate distribution is calculated by drawing a diameter (line) transversely from the center of a 12-inch wafer and dividing the standard deviation of the polishing rates measured at 10 mm intervals on the diameter (line) by the average polishing rate. Through this, it may be numerically understood how evenly the polished product is polished overall.

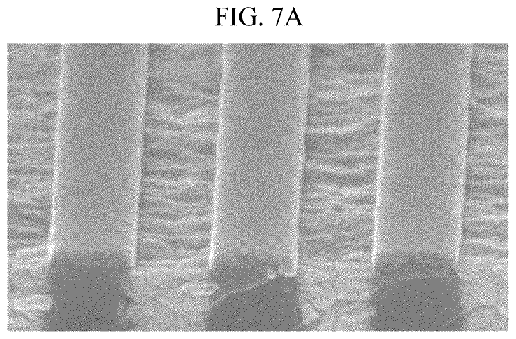

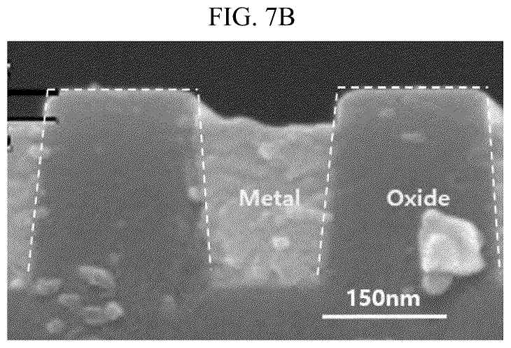

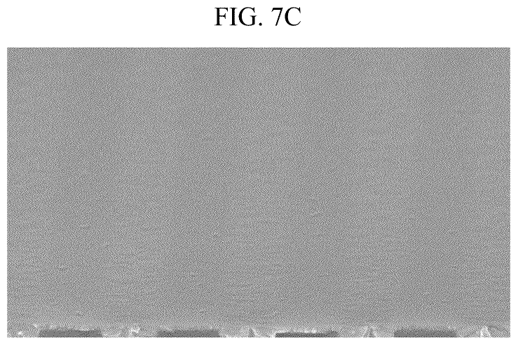

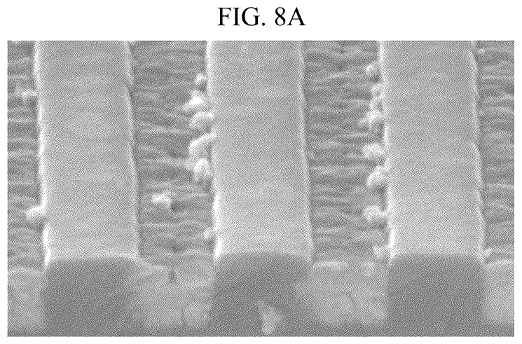

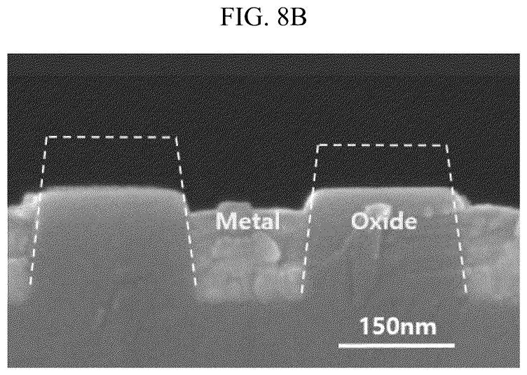

The results are shown in FIGS. 7A to 8B and recorded in Table 3.

FIG. 7A is an SEM image of a surface of a polished product of chemical mechanical polishing according to Example 4, FIG. 7B is an SEM image of a cross-section of a polished product of chemical mechanical polishing according to Example 4, FIG. 7C is an SEM image of a surface of a polished product of chemical mechanical polishing according to Example 1, FIG. 8A is an SEM image of a surface of a polished product of chemical mechanical polishing according to Reference Example 1, and FIG. 8B is an SEM image of a cross-section of a polished product of chemical mechanical polishing according to Reference Example 1.

TABLE 3

| | Polishing rate distribution |
|---|---|
| Example 1 | 3.5 |
| Example 2 | 6.9 |
| Example 3 | 1.5 |

Referring to FIGS. 7A to 7C and Table 3, the polished products of the chemical mechanical polishing according to Examples are formed as a conductive pattern (i.e. a metal pattern embedded in the trench) with high surface flatness (low surface roughness) without any residue of an inorganic abrasive or polymer micelles, with almost no scratches or defects, and without substantial etching or erosion of an adjacent oxide film. In contrast, referring to FIGS. 8A and 8B, it may be seen that the polished product of the chemical mechanical polishing according to Reference Example has a large amount of inorganic abrasive residue remaining, numerous defects such as scratches, and a significant amount of adjacent oxide film etched or eroded.

The results from the chemical mechanical polishing according to Examples indicate that the chemical mechanical polishing may prevent defects such as scratches caused by inorganic abrasives and damage caused by inorganic abrasive residues, while exhibiting a good physical polishing effect and little chemical etching by the polymer and/or micelle, thereby exhibiting improved polishing performance.

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A polishing slurry, comprising:
a branched polymer including a hydrophobic unit, a micelle of the branched polymers, or a combination thereof, and
a dispersion medium.

2. The polishing slurry of claim 1, wherein the hydrophobic unit comprises a substituted or unsubstituted C1 to C30 alkyl group, a substituted or unsubstituted C3 to C30 cycloalkyl group, a substituted or unsubstituted C2 to C30 alkenyl group, a substituted or unsubstituted C3 to C30 cycloalkenyl group, a substituted or unsubstituted C2 to C30 alkynyl group, a substituted or unsubstituted C6 to C30 aromatic group, a substituted or unsubstituted siloxane group, or a combination thereof.

3. The polishing slurry of claim 1, wherein
the branched polymer further comprises a hydrophilic functional group positioned at a terminal end of the branched polymer, and
the hydrophilic functional group comprises a hydroxyl group, a sulfonate group, a carboxylate group, a phosphonate group, an ammonium group, a pyrrolidium group, an imidazolium group, an amino group, an amide group, an aldehyde group, a ketone group, an epoxide group, or a combination thereof.

4. The polishing slurry of claim 1, wherein the branched polymer comprises one or more structural units derived from glycerol, ethylene glycol, propylene glycol, ethylene imine, piperazine, trimethylolpropane, sorbitol, acrylic acid, methacrylic acid, a derivative thereof, or a combination thereof.

5. The polishing slurry of claim 4, wherein the branched polymer comprises 3 to 100 structural units.

6. The polishing slurry of claim 1, wherein the branched polymer comprises one or more structural units represented by Chemical Formula A and a terminal moiety represented by Chemical Formula B: 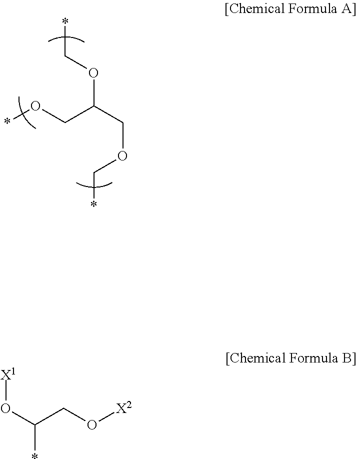
wherein, in Chemical Formula A or B,
X¹ and X² are each independently hydrogen or a hydrophilic functional group,
* indicates a linking point with an adjacent structural unit or the terminal moiety.

7. The polishing slurry of claim 6, wherein X¹ and X² are each independently hydrogen, a sulfonate group, a carboxylate group, a phosphonate group, an ammonium group, a pyrrolidium group, an imidazolium group, an amino group, an amide group, an aldehyde group, a ketone group, an epoxide group, or a combination thereof.

8. The polishing slurry of claim 1, wherein a weight average molecular weight of the branched polymer is about 300 grams per mole to about 10,000 grams per mole.

9. The polishing slurry of claim 1, wherein the micelle is in a form of an assembly of a plurality of the branched polymers, and
the micelle comprises
a core in which the hydrophobic units are assembled, and
a shell comprising a polymer segment, the polymer segment including hydrophilic functional groups and one or more structural units derived from glycerol, ethylene glycol, propylene glycol, ethylene imine, piperazine, trimethylolpropane, sorbitol, acrylic acid, methacrylic acid, a derivative thereof, or a combination thereof.

10. The polishing slurry of claim 1, wherein a particle size of the micelle measured by a dynamic light scattering method in an aqueous medium is about 1 nm to about 50 nm.

11. The polishing slurry of claim 1, wherein the branched polymer, the micelle, or a combination thereof is included in an amount of about 0.1 to about 30 wt % based on a total amount of the polishing slurry.

12. The polishing slurry of claim 1, further comprising an oxidizing agent,
wherein the polishing slurry does not comprise an inorganic abrasive.

13. A method of manufacturing a semiconductor device, the method comprising:
forming a conductive layer on a dielectric layer with a trench,
supplying polishing slurry onto the conductive layer, and
performing chemical mechanical polishing on the conductive layer to form a conductive pattern embedded in the trench,
wherein the polishing slurry comprises a branched polymer comprising a hydrophobic unit, a micelle of the branched polymers, or a combination thereof, and a dispersion medium.

14. The method of claim 13, wherein
the hydrophobic unit comprises a substituted or unsubstituted C1 to C30 alkyl group, a substituted or unsubstituted C3 to C30 cycloalkyl group, a substituted or unsubstituted C2 to C30 alkenyl group, a substituted or unsubstituted C3 to C30 cycloalkenyl group, a substituted or unsubstituted C2 to C30 alkynyl group, a substituted or unsubstituted C6 to C30 aromatic group, a substituted or unsubstituted siloxane group, or a combination thereof, and
the branched polymer further comprises
one or more structural units derived from glycerol, ethylene glycol, propylene glycol, ethylene imine, piperazine, trimethylolpropane, sorbitol, acrylic acid, methacrylic acid, a derivative thereof, or a combination thereof, and
a hydrophilic functional group comprising a hydroxyl group, a sulfonate group, a carboxylate group, a phosphonate group, an ammonium group, a pyrrolidium group, an imidazolium group, an amino group, an amide group, an aldehyde group, a ketone group, an epoxide group, or a combination thereof.

15. The method of claim 13, wherein the branched polymer comprises one or more structural units represented by Chemical Formula A and a terminal moiety represented by Chemical Formula B: 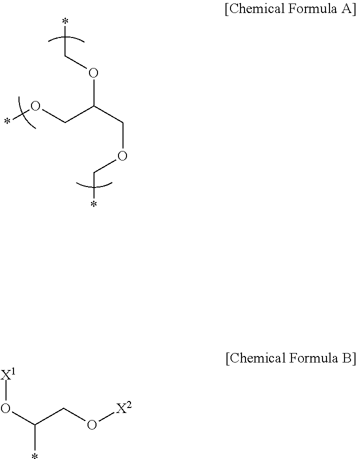
wherein, in Chemical Formula A or B,
X¹ and X² are each independently hydrogen or a hydrophilic functional group, and
* indicates a linking point with an adjacent structural unit or the terminal moiety.

16. The method of claim 13, wherein
the branched polymer, the micelle of the branched polymers, or a combination thereof is included in an amount of about 0.1 to about 30 wt % based on a total amount of the polishing slurry, and
a temperature of the polishing slurry in the performing of the chemical mechanical polishing is room temperature to about 70° C.

17. The method of claim 13, wherein
the micelle is in a form of an assembly of a plurality of the branched polymers, and
each micelle comprises
a core in which the hydrophobic units are assembled, and
a shell comprising a polymer segment, the polymer segment including hydrophilic functional groups and one or more structural units derived from glycerol, ethylene glycol, propylene glycol, ethylene imine, piperazine, trimethylolpropane, sorbitol, acrylic acid, methacrylic acid, a derivative thereof, or a combination thereof.

18. The method of claim 13, wherein a particle size of the micelle measured by a dynamic light scattering method in an aqueous medium is about 1 nm to about 50 nm.

19. A micelle of branched polymers, the micelle comprising:
a core in which the hydrophobic units are assembled, and
a shell comprising a polymer segment, the polymer segment including hydrophilic functional groups and one or more structural units derived from glycerol, ethylene glycol, propylene glycol, ethylene imine, piperazine, trimethylolpropane, sorbitol, acrylic acid, methacrylic acid, a derivative thereof, or a combination thereof,
wherein a particle size of the micelle measured by a dynamic light scattering method in an aqueous medium is about 1 nm to about 50 nm.

20. The micelle of claim 19, wherein
the hydrophobic unit comprises a substituted or unsubstituted C1 to C30 alkyl group, a substituted or unsubstituted C3 to C30 cycloalkyl group, a substituted or unsubstituted C2 to C30 alkenyl group, a substituted or unsubstituted C3 to C30 cycloalkenyl group, a substituted or unsubstituted C2 to C30 alkynyl group, a substituted or unsubstituted C6 to C30 aromatic group, a substituted or unsubstituted siloxane group, or a combination thereof, and
the hydrophilic functional groups comprise a hydroxyl group, a sulfonate group, a carboxylate group, a phosphonate group, an ammonium group, a pyrrolidium group, an imidazolium group, an amino group, an amide group, an aldehyde group, a ketone group, an epoxide group, or a combination thereof.
